(19) United States
(12) Patent Application Publication
(10) Pub. No.: US 2019/0113393 A1
(43) Pub. Date: Apr. 18, 2019

(54) TEMPERATURE SENSOR

(71) Applicant: RENESAS ELECTRONICS AMERICA INC., Milpitas, CA (US)

(72) Inventors: Tetsuo SATO, San Jose, CA (US); Tsuguyoshi HIROOKA, Takasaki (JP)

(21) Appl. No.: 16/163,411

(22) Filed: Oct. 17, 2018

Related U.S. Application Data
(60) Provisional application No. 62/573,844, filed on Oct. 18, 2017.

(51) Int. Cl. G01K 7/01; H03F 3/45; H03K 17/60

(52) U.S. Cl. CPC G01K 7/01; H03F 3/45475; H03F 2203/45116; H03F 2200/129; H03K 17/602

(57) ABSTRACT

A temperature sensor is disclosed. In one embodiment, the temperature sensor takes form in an integrated circuit that includes a plurality of first diodes connected in series between a first node and another node, and a plurality of second diodes connected in series between a second node and the other node. The integrated circuit includes a sub circuit coupled to the first and second nodes. The sub circuit the circuit is configured to generate an output voltage that depends on first and second voltages at the first and second nodes, respectively. The integrated circuit includes a first current source for generating a constant first current, wherein the first current or substantially all of the first current passes through the plurality of first diodes. A second current source is also provided on the integrated circuit for generating a constant second current, wherein the second current or substantially all of the second current passes through the plurality of second diodes. The plurality of first and second diodes are arranged on the integrated circuit so that they operate at a substantially equal temperature T.

### CROSS-REFERENCE TO RELATED APPLICATION

The present application claims priority to U.S. Provisional Patent Application No. 62/573,844, filed Oct. 18, 2017, the contents of which are incorporated herein by reference in their entirety.

### BACKGROUND OF THE INVENTION

There are numerous types of sensors for measuring temperature, including thermistor based sensors, thermocouple based sensors, diode based sensors, etc. One relative advantage of a diode based temperature sensor is that it can part of an integrated circuit (IC) formed on a semiconductor die at very low cost. Another advantage is that it occupies very little space on a semiconductor die. Still another advantage is that it can be placed on the die at a position very close to a target electronic component to be monitored, which means the diode based temperature sensor can provide a very accurate measure of the component's temperature.

A semiconductor diode, the most common type today, is a piece of semiconductor material with a p-n junction connected between two electrical terminals. A diode conducts current primarily in one direction; it has low (ideally zero) resistance to the current in one direction, and high (ideally infinite) resistance in the other. Semiconductor diodes begin conducting electricity only if a certain threshold voltage is present in the forward direction (a state in which the diode is said to be forward-biased). The voltage drop across a forward-biased diode varies little with current. By comparison the voltage drop varies substantially with temperature, and this effect can be used to measure temperature.

### SUMMARY OF THE INVENTION

A temperature sensor is disclosed. In one embodiment, the temperature sensor takes form in an integrated circuit that includes a plurality of first diodes connected in series between a first node and another node, and a plurality of second diodes connected in series between a second node and the other node. A first current source provides a constant first current, wherein the first current or substantially all of the first current passes through the plurality of first diodes. A second current source provides a constant second current, wherein the second current or substantially all of the second current passes through the plurality of second diodes. The integrated circuit also includes a sub circuit coupled to the first and second nodes. The sub circuit the circuit is configured to generate an output voltage that depends on first and second voltages at the first and second nodes, respectively. The plurality of first and second diodes are arranged on the integrated circuit so that they operate at a substantially equal temperature T.

### BRIEF DESCRIPTION OF THE DRAWINGS

In order that the advantages of the invention will be readily understood, a more particular description of the invention briefly summarized above will be rendered by reference to specific embodiments that are illustrated in the appended figures. Understanding that these figures depict only some embodiments of the invention and are not therefore to be considered to be limiting of its scope, the invention will be described and explained with additional specificity and detail through the use of the accompanying figures.

FIG. 1 illustrates a bandgap temperature sensor.

FIG. 2 illustrates a circuit that can be used in a diode-based temperature sensor circuit according.

FIG. 3 illustrates a diode-based temperature sensor circuit.

FIG. 4 illustrates another diode-based temperature sensor circuit.

FIG. 5 illustrates yet another diode-based temperature sensor circuit.

FIG. 6 illustrates an example circuit that can be used in diode-based temperature sensor circuit of FIG. 5.

FIG. 7 illustrates still another diode-based temperature sensor circuit.

FIG. 8 illustrates one more diode-based temperature sensor circuit.

The use of the same reference symbols in different drawings indicates similar or identical items.

### DETAILED DESCRIPTION

It will be readily understood that components of the invention, as generally described and illustrated in the figures herein, may be designed and arranged in a wide variety of different configurations. Thus, the following detailed description of the embodiments of the apparatus, system, and method of the invention, as represented in the attached figures, is not intended to limit the scope of the invention, as claimed, but is merely representative of selected embodiments of the invention.

The features, structures, or characteristics of the invention described throughout this specification may be combined in any suitable manner in one or more embodiments. For example, reference throughout this specification to “an embodiment,” “some embodiments,” or similar language means that a particular feature, structure, or characteristic described in connection with the embodiment is included in at least one embodiment of the invention. Thus, appearances of the phrases “in one embodiment,” “in other embodiments,” or similar language throughout this specification do not necessarily all refer to the same group of embodiments, and the described features, structures, or characteristics may be combined in any suitable manner in one or more embodiments.

A bandgap temperature sensor is a common form of diode-based temperature sensor that can be used in ICs to measure temperature therein. The principle of the bandgap sensor is that the forward voltage of a diode is temperature dependent. Diode-connected transistors can be employed as bandgap temperature sensors (i.e., one form of diode-based temperature sensors). A diode-connected transistor is two-terminal diode made out of a three-terminal transistor. A diode-connected bipolar junction transistor (BJT) is made by connecting the base and collector of a BJT. One characteristic of a diode-connected BJT is that it operates in the active region. The present invention will be described with reference to diode-connected BJTs, it being understood the present invention could employ p-n junction diodes or other devices (e.g., body diodes of MOSFETs).

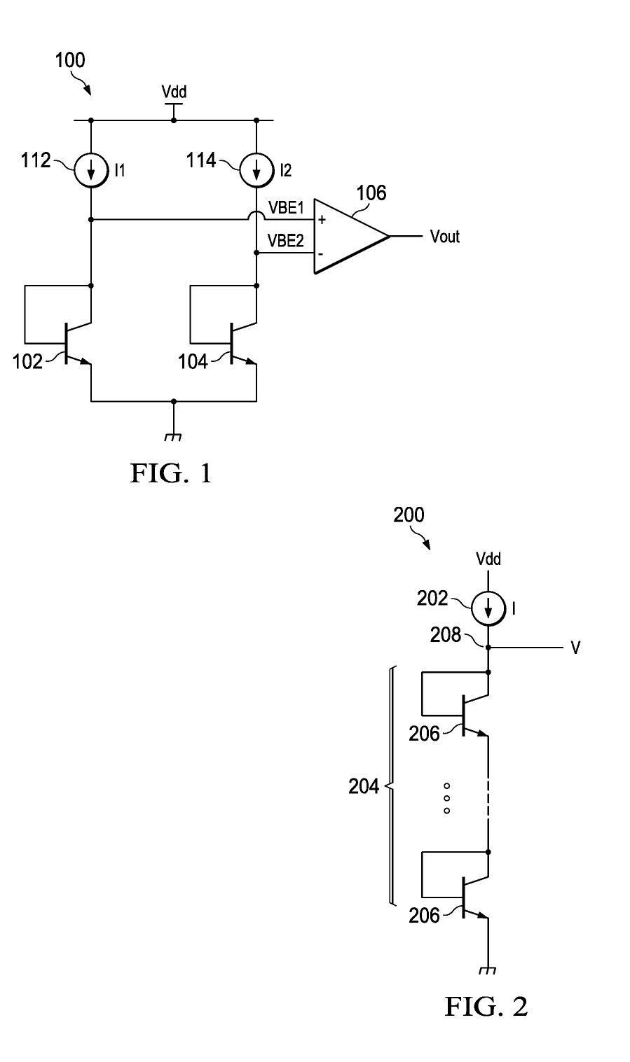

FIG. 1 shows a bandgap temperature sensor circuit 100 having two diode-connected BJTs 102 and 104, which are positioned adjacent to each other so that they are subjected to substantially the same thermal influences, and as a result they operate at substantially the same temperature T. The location of the diode-connected BJTs is important to accurate temperature measurement of a target component. Ideally the diode-connected BJTs should be in intimate physical contact with the target component whose temperature is being measured. This is not always possible. If direct thermal contact is not possible, it may be important to characterize the difference between the temperature of the diode-connected BJTs and the desired measurement point. In this way, a known offset may be used to compensate for the temperature difference and provide a more accurate determination of the target component's actual temperature.

Sensor circuit 100 includes current sources 112 and 114, which supply known constant currents I1 and I2 to diode-connected BJTs 102 and 104, respectively. The base-emitter voltage drops VBE1 and VBE2 across each of diode-connected BJTs 102 and 104, respectively, will vary in a predictable manner with changes in temperature T according to the following equations:

VBE1≅(kT/q)·ln(I1/(A1Iₛ))

and

VBE2≅(kT/q)·ln(I2/(A2Iₛ))

where k=Boltzmann's constant,

T=temperature in Kelvin,

q=charge on an electron,

A1 is the area of the emitter in diode-connected BJT 102,

A2 is the area of the emitter in diode-connected BJT 104, and

Iₛ is a saturation current constant.

One of ordinary skill understands that with emitter p-n junction areas A1=A2, but with I1≠I2, the difference in voltages VBE1−VBE2 yields:

VBE1−VBE2=ΔVBE=(kT/q)·ln(I1/I2) (1)

And one of ordinary skill understands that with different emitter p-n junction areas A1≠A2, but with I1=I2, VBE1−VBE2 yields:

VBE1−VBE2=ΔVBE=(kT/q)·ln(A2/A1) (2)

Importantly, both equations (1) and (2) lack Iₛ, whose value is very sensitive to the semiconductor manufacturing process variables. The other constants (i.e., k and q) are well known and do not vary with the semiconductor manufacturing process.

With continuing reference to FIG. 1, VBE1 and VBE2 are provided to the inverting and non-inverting inputs of differential amplifier 106. Vout is generated as a function of ΔVBE by amplifier 106. Vout can be conditioned, converted into a digital value, and subsequently processed based on equations (1) or (2) to yield T.

Several problems exist with sensor circuit 100. While ΔVBE is linear with a change of T, the range in which ΔVBE is linear, can be small. Perhaps more importantly, the rate at which ΔVBE changes with temperature (e.g., ΔVBE=0.2 mV/° C. with A2/A1=10 or I1/I2=10) can be very small in ΔVBE's linear range, which leads to small values for ΔVBE. Because ΔVBE is small, ΔVBE is susceptible to ground noise and/or leakage current, which means that sensor circuit may not be accurate enough for some temperature monitoring applications by itself. Additional components (e.g., chopper amplifier employing switched capacitor technology) can be used to enhance the accuracy of the sensor circuit, but these additional components are expensive to include, and they occupy valuable area on the semiconductor die. On the other hand, the adverse effects of ground noise and/or leakage current on T may be ameliorated if the ratio A2/A1 or I1/I2, and thus ΔVBE, is increased. For example, with I1=200.0 μA and I2=2.7 μA, or with I1=1.48 mA and I2=20.0 μA, ΔVBE=0.4 mV/° C. While ΔVBE=0.4 mV/° C. is less susceptible to ground noise and/or leakage current, employing a current source with I2=2.7 μA or I1=1.48 mA in an IC, however, presents engineering challenges. For example, too much power may be consumed with I1=1.48 mA, or leakage current issues may become more attenuated with I2=2.7 μA.

The present invention addresses the foregoing deficiencies of sensor circuit 100, and provides a diode-based temperature sensor circuit that uses one or more stacks of diode-connected BJTs (or similar devices) to measure temperature. Each stack employed in the present invention contains two or more diodes, two or more diode-connected BJTs, etc., coupled in series. The present invention will be described with reference to stacks of two or more diode-connected BJTs, it being understood the present invention should not be limited thereto. Each stack provides a temperature dependent voltage that is less susceptible to ground noise and/or leakage current when compared to a single diode-connected BJT, and as a result each stack provides for a more accurate measurement of temperature for a target electronic component.

FIG. 2 illustrates an example stack of diode-connected BJTs that can be used in a diode-based temperature sensor circuit according to one embodiment of the present invention. A current source 202 is connected in series with stack 204 of diode-connected BJTs 206, which are also connected in series as shown. Each of the diode-connected BJTs 206 should be similar in structure. At the very least, the areas of the p-n junctions at the emitters of diode-connected BJTs 206 should be substantially equal to each other.

Current source 202 provides a constant current I to stack 204. Diode-connected BJTs 206 are biased forward, and as a result current I or substantially all of current I flows through stack 204 to ground. This produces a voltage V≅N·(kT/q)·ln(I/(AIₛ)) at node 208, where N is the number of diode-connected BJTs 206 in stack 204, and A is the area of the emitter p-n junctions in diode-connected BJTs 206. One of ordinary skill in the art understands that voltage V is linearly dependent upon temperature T for a range of voltages. The remaining disclosure will describe stacks containing two diode-connected BJTs, it being understood the present invention should not be limited thereto.

Diode-connected BJTs 206 are arranged on a semiconductor die so that they operate at substantially the same temperature T. Diode-connected BJTs 206 should be placed on the die in close proximity to a target electronic component so that diode-connected BJTs 206 and the component have substantially the same temperature. Although not shown in FIG. 2, additional components such as amplifiers, analog-to-digital converters (ADCs), central processing units (CPUs), etc., can be formed on the semiconductor die. These additional components can act together to generate temperature T based on voltage V.

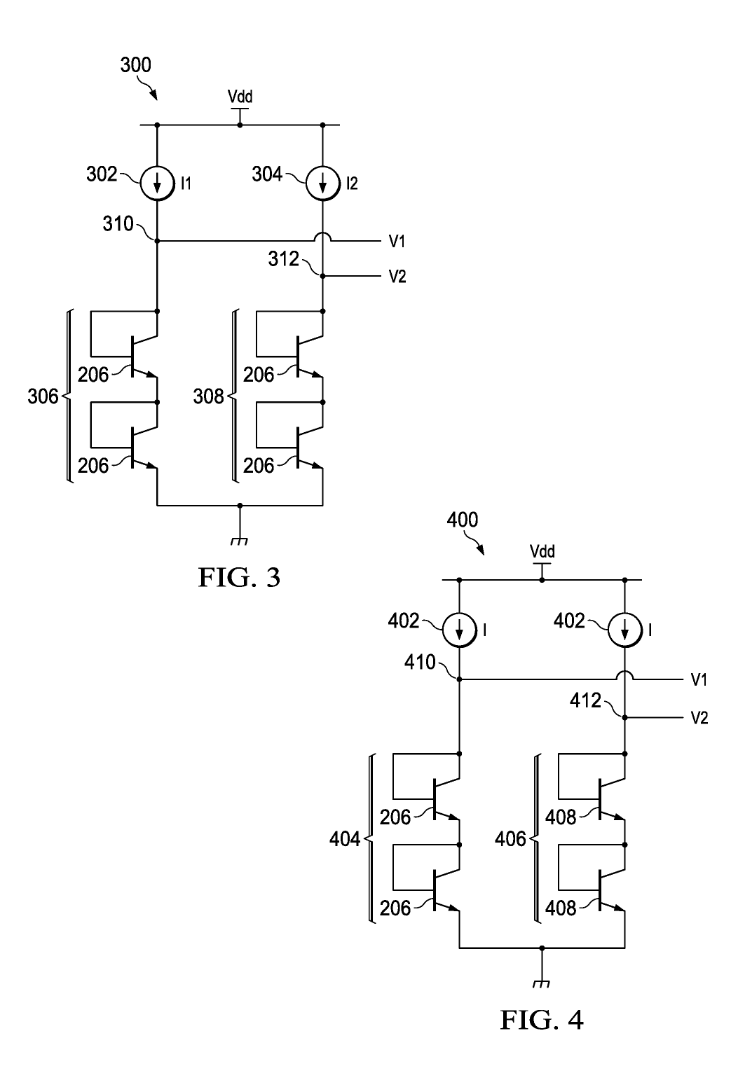

FIG. 3 illustrates an example of temperature sensor circuit 300 employing one embodiment of the present invention. As shown in FIG. 3, circuit 300 includes a pair of current sources 302 and 304 that generate constant, known currents I1 and I2, respectively. Each of these current sources 302 and 304 are connected in series with respective stacks 306 and 308 of diode-connected BJTs 206 as shown. The p-n junction areas at the emitters of diode-connected BJTs 206 should be substantially equal to each other.

Current I1 or substantially all of current I1 flows through stack 306 of diode-connected BJTs, while current I2 or substantially all of current I2 flows through the stack 308 of diode-connect BJTs. Voltages V1 and V2 are generated at nodes 310 and 312, respectively, and can be approximated to be equal to 2·(kT/q)·ln(I1/(AIₛ)) and 2·(kT/q)·ln(I2/(AIₛ)), respectively, where A is the area of the junction at the emitter of diode-connected BJTs 206. Because I1 is different in magnitude than I2, the voltages V1 and V2 should be different. However, one of ordinary skill understands that the difference between V1 and V2 can be represented as:

ΔV=V1−V2=2·(kT/q)·ln(I1/I2) ( 3)

Comparing equations (1) and (3) shows that both ΔVBE and ΔV are linearly dependent on T. ΔV, however, is two times greater than ΔVBE. Because ΔV is two times greater, ΔV is more sensitive than ΔVBE to a change in temperature T, and accordingly less susceptible to ground noise and/or leakage current. ΔV can be used to provide a relatively more accurate measurement of T.

FIG. 4 illustrates an alternative diode-based temperature sensor circuit 400 employing another embodiment of the present invention. As shown in FIG. 4, circuit 400 includes a pair of current sources 402, each generating constant, known current I. Current sources 402 are connected in series to respective stacks 404 and 406 as shown. Stack 404 contains diode-connected BJTs 206 coupled in series, and the areas A1 of the emitter p-n junctions are substantially equal to each other. Stack 406 contains diode-connected BJTs 408 coupled in series, and the areas A2 of the emitter p-n junctions are substantially equal to each other.

Voltages V1 and V2 are generated at nodes 410 and 412, respectively, and should be approximately equal to 2·(kT/q)·ln(I/(A1Iₛ)) and 2·(kT/q)·ln(I/(A2Iₛ)). With A1≠A2, the voltages V1 and V2 will not be the same.

However, one of ordinary skill understands that the difference between V1 and V2 can be represented as:

ΔV=V1−V2=2·(kT/q)·ln(A2/A1) (4)

Comparing equations (2) and (4) shows that both ΔVBE and ΔV are linearly dependent on T. However ΔV in equation (4) is two times greater than ΔVBE in equation (2). Because ΔV is two times greater, ΔV is more sensitive than ΔVBE to a change in temperature T, and accordingly less susceptible to ground noise and/or leakage current problems.

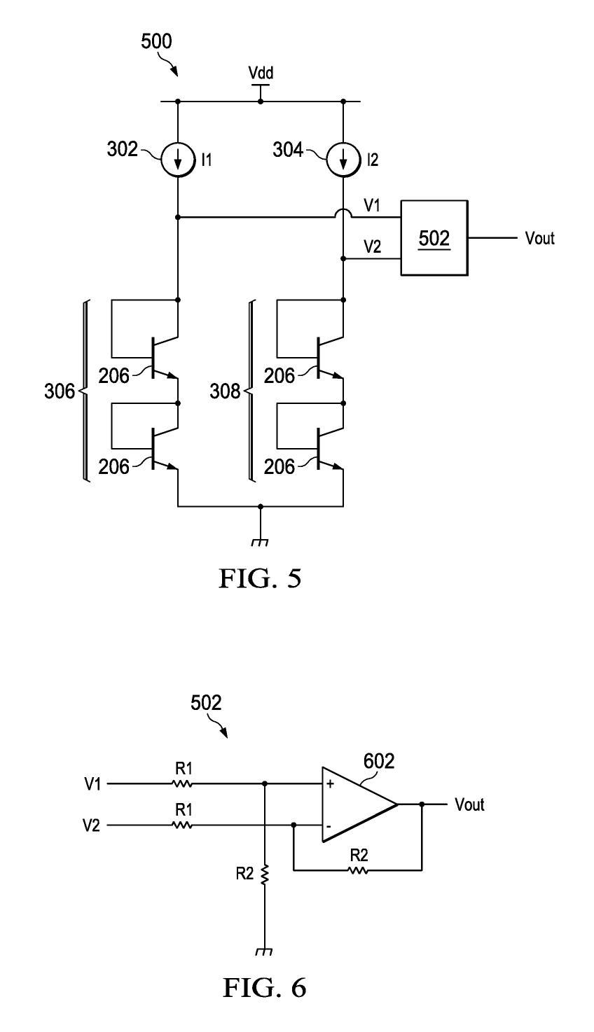

Although not shown in FIGS. 3 and 4, additional components may be added to the semiconductor die that contains diode-based sensor circuits employing the present invention, such as an amplifier, analog-to-digital converter (ADC), digital memory, central processing unit (CPU), etc. Collectively these additional components can receive and condition, convert, store and process voltages V1 and V2 to yield a digital value for T, which in turn can be compared to a threshold value; if T exceeds the threshold value, an alert can be generated. FIG. 5 illustrates the diode-based temperature sensor circuit 300 of FIG. 3 coupled to a sub circuit 502 that receives V1 and V2. Sub circuit 502 generates an output voltage Vout as a function of ΔV=V1 −V2. In one embodiment Vout =ΔV. Vout varies linearly with ΔV, which in turn varies linearly with temperature T for a range of ΔV. Thus, Vout varies linearly with temperature T.

Circuit 502 may take many different forms. Circuit 502 may include components that condition (e.g. filter) and/or amplify ΔV. Although not shown in FIG. 5, and ADC can convert the conditioned and/or amplified voltage ΔV into a digital equivalent for subsequent processing by a CPU executing instructions that are stored in a memory (not shown). The CPU can generate a digital equivalent for T in accordance with equations (3) or (4). FIG. 6 illustrates a component of an example circuit 502 that can be employed in embodiment shown in FIG. 5. FIG. 5 includes an operational amplifier 602 coupled to resistors R1 and R2 as shown. Circuit 502 amplifies ΔV. The gain A provided by circuit 502 depends on the resistive values of R1 and R2. With R2=10R1, gain A would equal 10, and thus Vout=10ΔV. Other circuits 502 are contemplated.

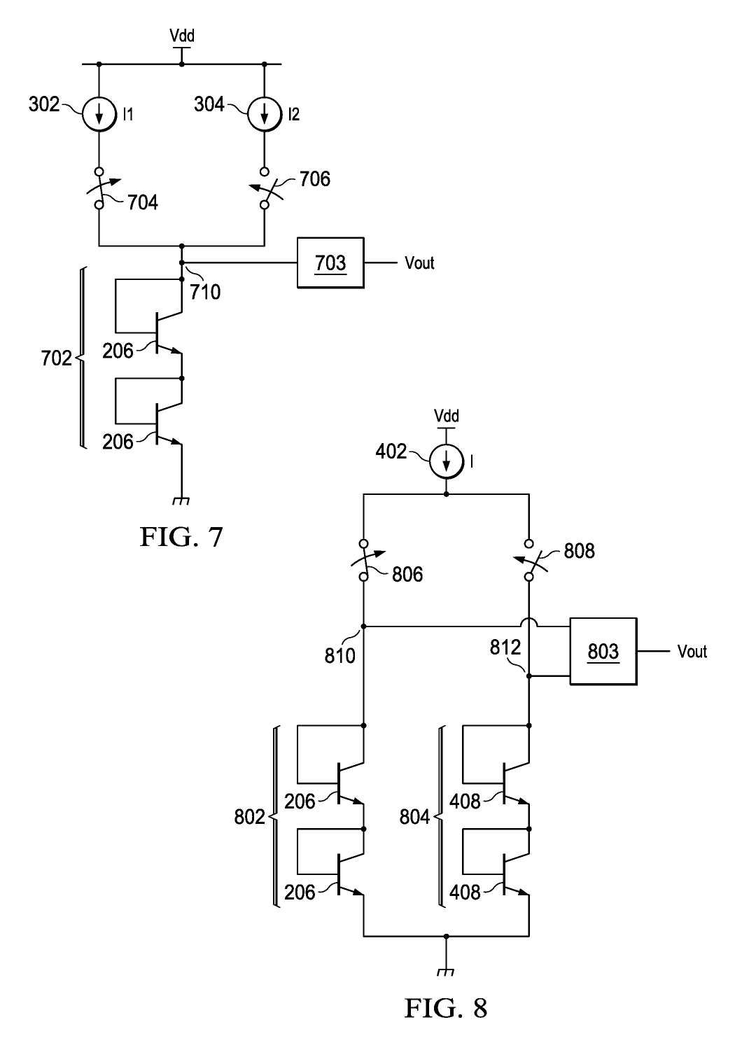

FIG. 7 illustrates another embodiment of a diode-based temperature sensor circuit 700 employing the present invention. Circuit 700 employs a single stack 702 of diode-connected BJTs 206, switches 704 and 706, and a circuit that includes current sources 302 and 304, which generate constant, known currents I1 and I2, respectively. In one embodiment, current I1 or I2 is provided by the current source via switches 704 or 706, respectively, when closed. Switches 704 and 706 are controlled by non-overlapping, complimentary pulses such that only one of the currents I1 and I2 is coupled to stack 702 at any given time. Circuit 703 may generate the non-overlapping, complimentary pulses that control switches 704 and 706.

The magnitudes of I2 and I1 should be substantially different. Current flow through diode stack 702 creates a voltage V at node 710 that approximately equals either 2·(kT/q)·ln(I1/(AIₛ)) or 2·(kT/q)·ln(I2/(AIₛ)) depending on whether switch 704 or switch 706 is closed. Circuit 703 generates an output voltage Vout as a function of the voltage at node 710. In one embodiment, Vout may be an analog signal. In another embodiment, Vout may be a digital value. In either embodiment Vout represents the difference between the voltage sampled at node 710 when switch 704 is closed and the voltage sampled at node 710 when switch 706 is closed. The difference ΔV in voltages should be proportional to 2·(kT/q)·ln(I1/I2).

In the digital version, circuit 703 includes an ADC for converting the voltages sampled at node 710, and a memory for storing the digital equivalents of the sampled voltages. A device such as CPU can subtract the digital equivalents stored in memory to yield Vout. This CPU can also be configured to process digital Vout based on equation (3) above to yield a digital equivalent for T. In the analog version, circuit 703 may include sample and hold capacitors and a differential amplifier. In this embodiment, a first switch is closed to connect a first sample and hold capacitor to node 710 while switch 704 is closed. The first sample and hold capacitor is charged to the voltage at node 710 while the first switch and switch 704 are closed. The first switch and switch 704 are then opened. A second switch is closed to connect a second sample and hold capacitor to node 710 while switch 706 is closed. The second sample and hold capacitor is charged to the voltage at node 710 while the second switch and switch 706 are closed. In this manner the first and second sample and hold capacitors are charged to the voltages at node 710 when currents I1 and I2 flow through stand 702, respectively. The first and second sample and hold capacitors can be connected to respective inputs of the differential amplifier, so that the differential amplifier generates analog Vout as a difference between the voltages held by the first and second sample and hold capacitors, respectively. An ADC can be provided that generates a digital equivalent of Vout for subsequent processing by a CPU to yield a digital value for T based on equation (3) above.

FIG. 8 shows yet another embodiment of a diode-based temperature sensor circuit 800 employing the present invention. In FIG. 8, a single current source 402 is alternatively connected to stacks 802 and 804 via switches 806 and 808, respectively. Stack 802 contains diode-connected BJTs 206 coupled in series. The areas A1 of emitter p-n junctions in diode-connected BJTs 206 should be substantially equal to each other. Stack 804 contains diode-connected BJTs 408 coupled in series. The areas A2 of the emitter p-n junctions in diode-connected BJTs 408 should be substantially equal to each other. Like the embodiment shown in FIG. 4, A1≠A2. Switches 806 and 808 are controlled by non-overlapping, complimentary pulses such that only one of the stacks 802 or 804 is energized with current I at any given time. Current I through diode stack 802 creates a voltage V1 at node 810 that approximately equals 2·(kT/q)·ln(I/(A1Iₛ)), and current I through stack 804 creates a voltage V2 at node 812 that approximately equals 2·(kT/q)·ln(I/(A2Iₛ)). In one embodiment circuit 803, which may generate the non-overlapping, complimentary pulses that control switches 806 and 808, samples voltages V1 and V2 when switches 806 and 808 are respectively closed. Circuit 803 generates an output voltage Vout as a function of the sampled voltages V1 and V2. In one embodiment circuit 803 subtracts sampled voltage V2 from sampled voltage V1 to create ΔV, which is proportional to 2·(kT/q)·ln(A2/A1). An ADC can be provided that generates a digital equivalent of Vout for subsequent processing by a CPU to yield a digital value for T.

Although the present invention has been described in connection with several embodiments, the invention is not intended to be limited to the specific forms set forth herein. On the contrary, it is intended to cover such alternatives, modifications, and equivalents as can be reasonably included within the scope of the invention as defined by the appended claims.

What is claimed is:

1. An integrated circuit comprising:
a plurality of first diodes connected in series between a first node and another node;
a plurality of second diodes connected in series between a second node and the other node;
a circuit coupled to the first and second nodes wherein the circuit is configured to generate an output voltage that depends on first and second voltages at the first and second nodes, respectively;
a first current source for generating a first current to be passed through the plurality of first diodes when the first current source is active;
a second current source for generating a second current to be passed through the plurality of second diodes when the second current source is active;
wherein the plurality of first and second diodes are configured in the integrated circuit to operate at a substantially equal temperature T.

2. The integrated circuit of claim 1 wherein the first and second diodes are configured so that current density at p-n junction areas of the first diodes is different than the current density at p-n junction areas of the second diodes.

3. The integrated circuit of claim 1 further comprising a differential amplifier comprising inputs coupled to the first and second nodes.

4. The integrated circuit of claim 1 wherein each of the plurality of first and second diodes is part of a respective bipolar junction transistor (BJT) with its base connected to its collector.

5. The integrated circuit of claim 1 wherein the output voltage depends on the temperature T.

6. The integrated circuit of claim 1 wherein the output voltage depends on a difference between the first and second voltages.

7. An integrated circuit comprising:
a first temperature sensor circuit component comprising:
a plurality of first diodes coupled in series between a first node and another node;
a first current source for generating a first current;
wherein the plurality of first diodes are coupled to the first current source so that the first current flows through the plurality of first diodes;
wherein p-n junction areas of first diodes are substantially equal;
a circuit coupled to the first node and configured to generate a signal based on a first voltage at the first node.

8. The integrated circuit of claim 7 further comprising:
a second temperature sensor circuit component comprising:
a plurality of second diodes coupled in series between a second node and the other node;
a second current source for generating a second current;
wherein the plurality of second diodes are coupled to the second current source so the second current flows through the plurality of first second diodes;
wherein p-n junction areas of the of second diodes are substantially equal;
wherein the circuit is coupled to the second node and configured to generate the signal based a second voltage at the second node.

9. The integrated circuit of claim 8 wherein the first and second diodes are configured so that the current density at p-n junction areas of the first diodes is different than the current density at p-n junction areas of the second diodes.

10. The integrated circuit of claim 8 further comprising a differential amplifier comprising inputs coupled to the first and second nodes.

11. The integrated circuit of claim 8 wherein each of the plurality of first and second diodes is part of a respective bipolar junction transistor (BJT) with its base connected to its collector.

12. The integrated circuit of claim 8 wherein the signal depends on a temperature T at which at least one of the plurality of first diodes operates.

13. The integrated circuit of claim 8 wherein the signal depends on a difference between the first and second voltages.

14. The integrated circuit of claim 8 wherein the circuit comprises an operational amplifier with inputs coupled to the first and second nodes, respectively, via first and second resistors, respectively, wherein the operational amplifier is configured to generate an output voltage based on first and second voltages at the first and second nodes, respectively.

15. An integrated circuit comprising:
a stack of first diodes coupled in series between a first node and another node, wherein p-n junction areas of first diodes are substantially equal;
a first current source for generating a first current;
a first switch for selectively coupling the first current source to the stack of first diodes so that the first current flows through the stack of first diodes when the first switch is closed;
a circuit coupled to the first node and configured to generate a signal based on a first voltage generated at the first node when the first switch is closed.

16. The integrated circuit of claim 15 further comprising:
a second current source for generating a second current;
a second switch for selectively coupling the second current source to the stack of first diodes so that the second current flows through the stack of first diodes when the second switch is closed;
wherein the circuit is configured to sample a second voltage generated at the first node when the second switch is closed and the first switch is opened;
wherein the circuit is configured to generate the signal based on the first voltage and the sampled second voltage.

17. The integrated circuit of claim 15 further comprising:
a stack of second diodes coupled in series between a second node and the other node,
wherein p-n junction areas of second diodes are substantially equal, and wherein p-n junction areas of the first diodes are substantially different when compared to the p-n junction areas of the second diodes;
a second switch for selectively coupling the first current source to the stack of second diodes so that substantially all of the first current flows through the stack of second diodes when the second switch is closed;
wherein the circuit is configured to sample the first voltage generated at the first node when the first switch is closed and the second switch is opened;
wherein the circuit is configured to generate the signal based on the sampled first voltage and a second voltage generated at the second node when the second switch is closed and the first switch is opened.

18. The integrated circuit of claim 15 wherein each of the first diodes is part of a respective bipolar junction transistor (BJT) with its base connected to its collector.

19. The integrated circuit of claim 16 wherein the signal depends on a difference between the first voltage and the sampled second voltage.

20. The integrated circuit of claim 17 wherein the signal depends on a difference between the sampled first voltage and the second voltage.

21. An integrated circuit comprising:
a first circuit configured to generate a first current or a second current, wherein a magnitude of the first current is different from a magnitude of the second current;
series connected diodes coupled to receive the first current or the second current, wherein the series connected diodes are coupled between first and second nodes;
a second circuit coupled to the first node;
wherein the second circuit is configured to sample a first voltage at the first node when the first current flows through the series connected diodes;
wherein the second circuit is configured to sample a second voltage at the first node when the second current flows through the series connected diodes;
wherein the second circuit is configured to calculate a temperature T of the series connected diodes based on the sampled first voltage and the sampled second voltage.

22. The integrated circuit of claim 21:
wherein the second circuit comprises an analog-to-digital convertor (ADC) for converting the first and second sampled voltages into first and second digital values, respectively;
wherein the second circuit comprises a memory for storing the first and second digital values;
wherein the second circuit comprises a device for calculating temperature T as a function of the first and second digital values.

23. The integrated circuit of claim 21;
wherein the second circuit comprise a sample and hold circuit;
wherein the sample and hold circuit comprises a capacitor and a switch, wherein the switch is coupled between the first node and the capacitor;
wherein the switch closes and couples the capacitor to the first node only when the first current flows through the series coupled diodes.

24. The integrated circuit of claim 1 wherein p-n junction areas of the first and second diodes are substantially equal.

25. The integrated circuit of claim 1 wherein p-n junction areas of the first diodes are substantially equal in area, wherein p-n junction areas of the second diodes are substantially equal in area, and wherein the p-n junction areas of the first diodes are substantially unequal when compared to the p-n junction areas of the second diodes.
